(19) United States
(12) Patent Application Publication
(10) Pub. No.: US 2025/0074197 A1
(43) Pub. Date: Mar. 6, 2025

(54) APPARATUS FOR MANAGING BATTERY AND METHOD THEREOF

(71) Applicants: HYUNDAI MOTOR COMPANY, SEOUL (KR); KIA CORPORATION, SEOUL (KR)

(72) Inventors: Yoo Hong Jang, Suwon-si (KR); Yoon Sung Choi, Hwaseong-si (KR); Sang Jin Lee, Goyang-si (KR); Hyo Kyung Lee, Anyang-si (KR); Yo Han Baek, Anyang-si (KR)

(21) Appl. No.: 18/533,702

(22) Filed: Dec. 8, 2023

(30) Foreign Application Priority Data
Aug. 29, 2023 (KR) 10-2023-0114010

(51) Int. Cl. B60L 3/00; B60L 58/12; G01R 31/3842

(52) U.S. Cl. CPC B60L 3/0046; B60L 58/12; G01R 31/3842; B60L 2240/547

(57) ABSTRACT

An apparatus for managing a battery includes a voltage sensor that measures a voltage of a battery cell mounted on a vehicle, and a processor that determines a short circuit risk of the battery cell. The processor may determine a self-discharge current of the battery cell during a self-discharge period in which a voltage drop of the battery cell occurs, determine an average voltage of the battery cell during the self-discharge period, determine a total self-discharge resistance of the battery cell based on the self-discharge current and the average voltage, determine a short circuit resistance of the battery cell based on the total self-discharge resistance, and notify the short circuit risk based on a fact that the short circuit resistance is less than a threshold

### CROSS REFERENCE TO RELATED APPLICATIONS

This application claims the benefit of priority to Korean Patent Application No. 10-2023-0114010, filed in the Korean Intellectual Property Office on Aug. 29, 2023, the entire contents of which are incorporated herein by reference.

### TECHNICAL FIELD

The present disclosure relates to an apparatus for managing a battery and a method thereof, and more particularly, to a technology for determining a short circuit risk of a battery cell.

### BACKGROUND

Eco-friendly vehicles using electric energy as a power source, such as electric vehicles or hybrid vehicles, are equipped with batteries that store and output electric energy. A battery may include a battery pack having a plurality of battery cells.

Because a battery mounted in an electric vehicle involve a risk of fire due to internal short circuit, quality inspection is performed after manufacturing battery cells. Through quality inspection, defective battery cells generated during the manufacturing process may be detected.

However, even though a battery cell is determined to be normal in the manufacturing process, when the battery cell deteriorates during use or continues to undergo physical shock, a short circuit may occur inside the battery cell, and small short circuits may continuously accumulate to cause a hard short circuit.

Therefore, there is a need to provide a scheme capable of determining a short circuit risk of a battery cell even after the battery cell is manufactured.

### SUMMARY

The present disclosure has been made to solve the above-mentioned problems occurring in the prior art while advantages achieved by the prior art are maintained intact.

An aspect of the present disclosure provides an apparatus for managing a battery and a method thereof that may determine a short circuit risk of a battery cell.

Another aspect of the present disclosure provides an apparatus for managing a battery and a method thereof that may determine whether a short circuit phenomenon is accelerated during use of a battery cell.

Still another aspect of the present disclosure provides an apparatus for managing a battery and a method thereof that may reduce a fire risk due to a short circuit by determining a short circuit risk before the short circuit occurs.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, an apparatus for managing a battery includes a voltage sensor that measures a voltage of a battery cell mounted on a vehicle, and a processor that determines a short circuit risk of the battery cell. The processor may determine a self-discharge current of the battery cell during a self-discharge period in which a voltage drop of the battery cell occurs, determine an average voltage of the battery cell during the self-discharge period, determine a total self-discharge resistance of the battery cell based on the self-discharge current and the average voltage, determine a short circuit resistance of the battery cell based on the total self-discharge resistance, and notify the short circuit risk based on a fact that the short circuit resistance is less than a threshold resistance.

According to an embodiment, the processor may determine a self-discharge capacity proportional to the voltage drop, and determine the self-discharge current by dividing the self-discharge capacity by the self-discharge period.

According to an embodiment, the processor may obtain a first SOC corresponding to a first voltage of the battery cell measured at a start timing of the self-discharge period, obtain a second SOC corresponding to a second voltage of the battery cell measured at an end timing of the self-discharge period, and obtain a difference between the first SOC and the second SOC as the self-discharge capacity.

According to an embodiment, the processor may determine a maximum voltage of the battery cell as the first voltage within a first preset stabilization period after operation of the vehicle is terminated.

According to an embodiment, the processor may determine a minimum voltage of the battery cell as the first voltage within a second preset stabilization period after charging of the battery cell is terminated.

According to an embodiment, the processor may determine, as the second voltage, a minimum voltage among voltages of the battery cell measured before an ignition-on signal of the vehicle is detected.

According to an embodiment, the processor may determine the average voltage by averaging the first voltage and the second voltage.

According to an embodiment, the processor may skip a procedure of determining the short circuit resistance when the self-discharge period is less than a preset threshold period.

According to an embodiment, the processor may determine the short circuit resistance based on the total self-discharge resistance, a separator resistance of the battery cell, and a resistance of a balancing switch for balancing the battery cell.

According to an embodiment, the processor is configured to set a size of the threshold resistance to be larger as the self-discharge period is longer.

According to an embodiment, the processor may determine a change in the short circuit resistance when the short circuit resistance is less than the threshold resistance, and notify the short circuit risk when the short circuit resistance gradually decreases.

According to another aspect of the present disclosure, a method of managing a battery includes determining a self-discharge current of a battery cell during a self-discharge period in which a voltage drop of the battery cell occurs, determining an average voltage of the battery cell during the self-discharge period, determining a total self-discharge resistance of the battery cell based on the self-discharge current and the average voltage, and determining a short circuit resistance of the battery cell based on the total self-discharge resistance, and notifying the short circuit risk based on a fact that the short circuit resistance is less than a threshold resistance.

According to an embodiment, the determining of the self-discharge current may include determining a self-discharge capacity proportional to the voltage drop, and determining the self-discharge current by dividing the self-discharge capacity by the self-discharge period.

According to an embodiment, the determining of the self-discharge current may include obtaining a first SOC corresponding to a first voltage of the battery cell measured at a start timing of the self-discharge period, obtaining a second SOC corresponding to a second voltage of the battery cell measured at an end timing of the self-discharge period, and obtaining a difference between the first SOC and the second SOC as the self-discharge capacity.

According to an embodiment, the obtaining of the first SOC may include determining a maximum voltage of the battery cell as the first voltage within a first preset stabilization period after operation of the vehicle is terminated.

According to an embodiment, the obtaining of the first SOC may include determining a minimum voltage of the battery cell as the first voltage within a second preset stabilization period after charging of the battery cell is terminated.

According to an embodiment, the obtaining of the second SOC may include detecting an ignition-on signal of the vehicle, and determining, as the second voltage, a minimum voltage among voltages of the battery cell measured before the ignition-on signal of the vehicle is detected.

According to an embodiment, the determining of the average voltage may include obtaining the average voltage by averaging the first voltage and the second voltage.

According to an embodiment, the method may further include comparing the self-discharge period with a preset threshold period, and skipping a procedure of determining the short circuit resistance when the self-discharge period is less than a preset threshold period.

According to an embodiment, the notifying of the short circuit risk may further include setting a size of the threshold resistance to be larger as the self-discharge period is longer.

### BRIEF DESCRIPTION OF THE FIGURES

The above and other objects, features and advantages of the present disclosure will be more apparent from the following detailed description taken in conjunction with the accompanying drawings:

FIG. 1 is a diagram illustrating an apparatus for managing a battery according to an embodiment of the present disclosure;

FIG. 2 is a flowchart illustrating a method of managing a battery according to an embodiment of the present disclosure;

FIG. 3 is a diagram illustrating self-discharge of a battery cell after vehicle operation ends;

FIG. 4 is a diagram illustrating self-discharge of a battery cell after charging of the battery is completed;

FIG. 5 is a diagram illustrating a method of obtaining an end voltage of a self-discharge period according to another embodiment;

FIG. 6 is a diagram illustrating modeling of a battery cell;

FIG. 7 is a diagram illustrating a battery cell modeled by simplifying anode and cathode electrodes shown in FIG. 6 into OCV;

FIG. 8 is a diagram illustrating the tendency of heat generation due to short circuit resistance;

FIG. 9 is a diagram illustrating the error of a voltage sensor;

FIG. 10 is a diagram illustrating a method of determining a short circuit risk according to another embodiment of the present disclosure;

FIG. 11 is a flowchart illustrating a method of managing a battery according to another embodiment of the present disclosure; and

FIG. 12 is a block diagram illustrating a computing system according to an embodiment of the present disclosure.

### DETAILED DESCRIPTION

Hereinafter, some embodiments of the present disclosure will be described in detail with reference to the exemplary drawings. In adding the reference numerals to the components of each drawing, it should be noted that the identical or equivalent component is designated by the identical numeral even when they are displayed on other drawings. Further, in describing the embodiment of the present disclosure, a detailed description of the related known configuration or function will be omitted when it is determined that it interferes with the understanding of the embodiment of the present disclosure.

In describing the components of the embodiment according to the present disclosure, terms such as first, second, A, B, (a), (b), and the like may be used. These terms are merely intended to distinguish the components from other components, and the terms do not limit the nature, order or sequence of the components. Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

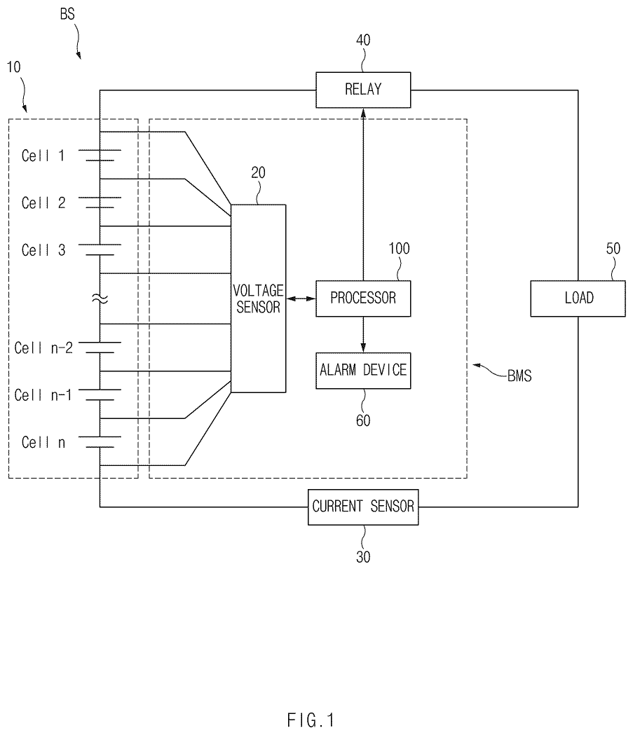

Hereinafter, embodiments of the present disclosure will be described in detail with reference to FIGS. 1 to 12.

FIG. 1 is a diagram illustrating an apparatus BS for managing a battery according to an embodiment of the present disclosure. The apparatus BS for managing a battery according to an embodiment of the present disclosure may be provided to manage the battery mounted on an electric vehicle. The electric vehicles may include a fuel cell for charging the battery. The fuel cell may convert chemical energy into electrical energy by electrochemically reacting fuel gas and oxygen. The fuel cell may have a stack structure in which multiple cells are stacked, and each cell may generate electrical energy by receiving hydrogen gas contained in fuel gas and air and inducing oxidation and reduction reactions. The fuel cell may be protected from the outside by an end plate, and may include an electrode-electrolyte assembly (Membrane & Electrode Assembly: MEA) that oxidizes/reduces hydrogen gas and air, and at least one separator that supplies fuel gas and air to the electrode-electrolyte assembly.

The vehicle mentioned in describing an embodiment of the present disclosure may mean a vehicle equipped with the apparatus BS for managing a battery shown FIG. 1.

Referring to FIG. 1, an apparatus BMS for managing a battery according to an embodiment of the present disclosure may include a voltage sensor 20, a current sensor 30, and a processor 100.

A battery 10 may include a plurality of battery cells Cell #1 to Cell #n connected in series with each other. The battery 10 may provide a voltage to a load 50 according to the switching operation of a relay 40. Hereinafter, one of the battery cells Cell #1 to Cell #n will be referred to as a battery cell CE. The battery 10 may be electrically connected to the load 50 through the switching operation of the relay 40 and may provide the voltage to the load 50. The load 50 may be devices driven by receiving the voltage from the battery 10, and may include a driving motor, electrical components, and the like. The drive motor may be used to drive wheels of a vehicle.

The voltage sensor 20 can measure the voltage of each of the battery cells Cell #1 to Cell #n.

The current sensor 30 may measure a current of the battery 10.

The processor 100 may determine a short circuit risk of the battery cell CE based on the voltage of the battery cell CE.

To this end, the processor 100 may determine a self-discharge period during which a voltage drop of the battery cell CE occurs based on the change in voltage of the battery cell CE measured by the voltage sensor 20.

The self-discharge period may be a period in which a voltage drop occurs due to leakage current of the battery cell CE when the vehicle is not driven. The self-discharge period may be a period after the battery cell CE is charged or a period after the battery cell CE is discharged. For example, the start timing of the self-discharge period may be determined within a preset first stabilization period after operation of the vehicle ends. Alternatively, the start timing of the self-discharge period may be determined within a preset second stabilization period after charging of the battery cell CE is terminated. The first stabilization period or the second stabilization period may be set to the same time period. For example, the first stabilization period and the second stabilization period may be set to 2 hours. Alternatively, the first stabilization period and the second stabilization period may be set to different time periods.

In addition, the processor 100 may determine the self-discharge current in the self-discharge period based on the voltage drop of the battery cell CE.

The self-discharge current may be obtained by dividing the self-discharge capacity by the self-discharge period.

The self-discharge capacity may be obtained to be proportional to the voltage drop in the self-discharge period. For example, the processor 100 ma obtain a first voltage corresponding to the voltage of the battery cell CE at the start timing of the self-discharge period, and obtain a second voltage corresponding to the voltage of the battery cell CE at the end timing of the self-discharge period. Then, the processor 100 may obtain a first SOC corresponding to the first voltage and a second SOC corresponding to the second voltage. The first voltage may be the maximum voltage of the battery cell CE within the first stabilization period. Alternatively, the first voltage may be the minimum voltage of the battery cell CE within the second stabilization period. The processor 100 may obtain the first SOC and the second SOC by using an open circuit voltage (OCV)-state of charge (SOC) table. In addition, the processor 100 may obtain self-discharge capacity by determining the difference between the first SOC and the second SOC.

In addition, the processor 100 may determine the average voltage of the battery cell CE in the self-discharge period.

The average voltage of the battery cell CE may be the average of the first voltage and the second voltage.

In addition, the processor 100 may determine the total self-discharge resistance of the battery cell CE based on the self-discharge current and average voltage of the battery cell CE.

In addition, the processor 100 may determine the short circuit resistance based on the total self-discharge resistance of the battery cell CE. The short circuit resistance may refer to the resistance in a short area when a short circuit occurs in the battery cell CE.

In addition, the processor 100 may compare the short circuit resistance with a threshold resistance, and when the short circuit resistance is less than the threshold resistance, the processor 100 may notify the short circuit risk through an alarm device 60.

The processor 100 may detect the short circuit resistance by performing an algorithm stored in a memory (not shown) and output a warning based on the short circuit resistance. The memory may include a hard disk drive, a flash memory, an electrically erasable programmable read-only memory (EEPROM), a static RAM (SRAM), a ferro-electric RAM (FRAM), a phase-change RAM (PRAM), a magnetic RAM (MRAM), a dynamic random access memory (DRAM), a synchronous dynamic random access memory (SDRAM), a double date rate-SDRAM (DDR-SDRAM), and the like.

The memory may be included inside the processor 100 or may be arranged outside the processor 100.

The alarm device 60 may be used to notify the driver of the vehicle, a server outside the vehicle, or another vehicle of the short circuit risk. The alarm device 60 may use at least one of haptic devices combined with a display, a speaker, or a steering wheel. Alternatively, the alarm device 60 may include a communication module for notifying a server outside the vehicle or another vehicle of the short circuit risk. The communication module may transmit and receive radio signals with at least one of a base station, an external terminal, and a center on a mobile communication network constructed according to technical standards or communication schemes for mobile communication. For example, the communication module may perform communication based on global system for mobile communication (GSM), code division multi access (CDMA), code division multi access 2000 (CDMA2000), enhanced voice-data optimized or enhanced voice-data only (EV-DO), wideband CDMA (WCDMA), high speed downlink packet access (HSDPA), high speed uplink packet access (HSUPA), long term evolution (LTE), long term evolution-advanced (LTEA), and the like.

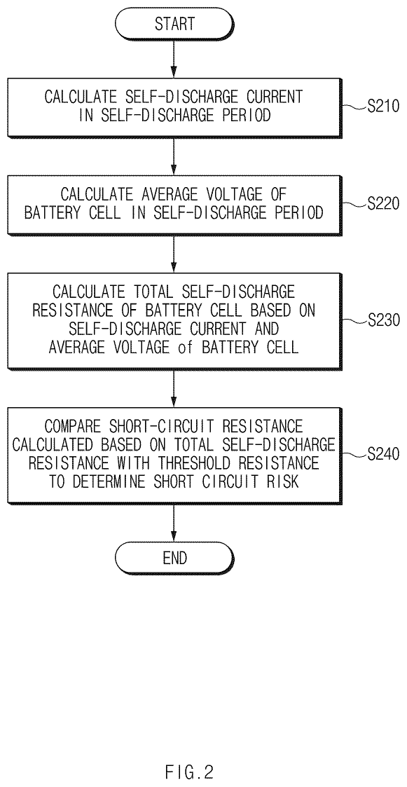

FIG. 2 is a flowchart illustrating a method of managing a battery according to an embodiment of the present disclosure. The procedures shown in FIG. 2 may be controlled by a processor. With reference to FIGS. 1 and 2, a method of managing a battery according to an embodiment of the present disclosure will be described below.

In S210, the processor 100 may determine the self-discharge current in the self-discharge period of the battery cell CE.

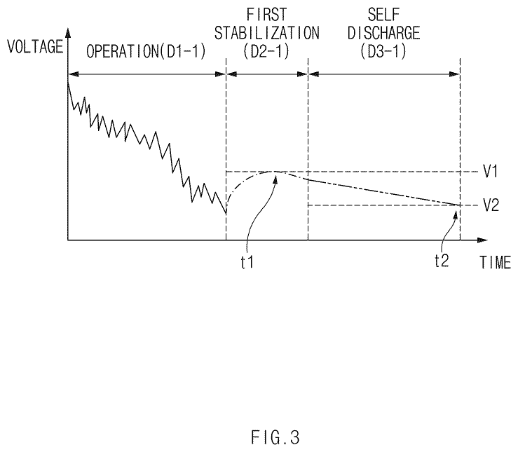

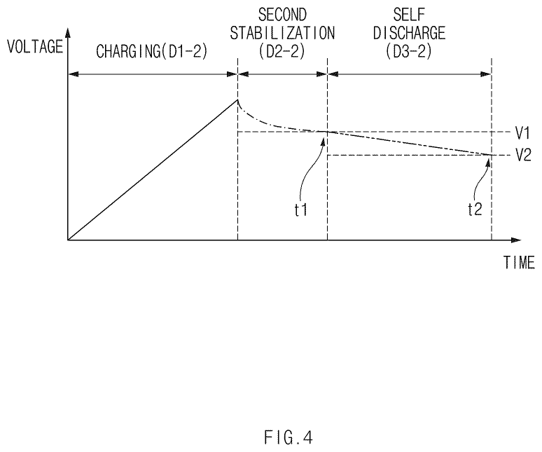

The start timing of the self-discharge period may be determined within the first stabilization period and the second stabilization period. In addition, the end timing of the self-discharge period may be before the ignition on signal of the vehicle is confirmed. The self-discharge period will be described below with reference to FIGS. 3 and 4.

FIG. 3 is a diagram illustrating self-discharge of a battery cell after vehicle operation ends. FIG. 3 illustrates the voltage change of the battery cell over time.

Referring to FIG. 3, a vehicle operation period D1-1 may be a period in which the battery cell CE is discharged while providing a voltage to the load 50. Accordingly, the voltage of the battery cell CE tends to gradually decrease during the vehicle operation period D1-1. In the vehicle operation period D1-1, the voltage of the battery cell CE may be measured lower than the open-circuit voltage due to a polarization phenomenon. Accordingly, after the vehicle operation period D1-1 ends, the voltage of the battery cell CE may become somewhat higher in a first stabilization period D2-1.

The first stabilization period D2-1 may be a period in which the voltage of the battery cell CE is stabilized after the discharge of the battery cell CE ends. In the first stabilization period D2-1, the voltage of the battery cell CE may increase to the open-circuit voltage. The first stabilization period D2-1 may be a preset period, and may be set to a time period sufficient for the voltage of the battery cell CE to increase to the open-circuit voltage. For example, the first stabilization period D2-1 may be set to 2 hours.

In the first stabilization period D2-1, the voltage of the battery cell CE may be stabilized to increase to the open-circuit voltage, and then may gradually decrease due to self-discharge. For example, in the first stabilization period D2-1, the voltage of the battery cell CE may be a first voltage V1 at a first timing t1 which is the highest voltage and may gradually decrease.

The first stabilization period D2-1 may be preset to a certain time, and after the voltage of the battery cell CE is stabilized, the battery cell CE may be self-discharged within the first stabilization period D2-1. The voltage of the battery cell CE may be lowered again due to self-discharge. Accordingly, the processor 100 may determine the first timing t1, at which the voltage of the battery cell CE is measured to be highest in the first stabilization period D2-1, as the start timing of the self-discharge period.

After the first stabilization period D2-1, the battery cell CE may be self-discharged in a self-discharge period D3-1.

The self-discharge period D3-1 may end at the timing when the vehicle resumes operation. For example, the processor 100 may determine the end of the self-discharge period D3-1 in response to an ignition-on (IG on) signal.

The processor 100 may determine the voltage of the battery cell CE measured at the end timing of the self-discharge period as a second voltage V2. In more detail, the processor 100 may determine, as the second voltage V2, the voltage of the battery cell CE measured within a certain time from the timing at which the ignition-on signal is detected. Alternatively, the processor 100 may obtain, as the second voltage V2, the minimum voltage among the voltages of the battery cell CE measured in the period before the ignition-on signal is detected.

FIG. 4 is a diagram illustrating self-discharge of a battery cell after charging of the battery is completed.

Referring to FIG. 4, the voltage of the battery cell CE may gradually increase during a charging period D1-2.

After the charging period D1-2 ends, the voltage of the battery cell CE may be somewhat lowered and stabilized in the second stabilization period D2-2. Accordingly, after the charging period D1-2 ends, the voltage of the battery cell CE may be somewhat lower in the second stabilization period D2-2.

The second stabilization period D2-2 may be a period in which the voltage of the battery cell CE is stabilized after charging of the battery cell CE is completed. In the second stabilization period D2-2, the voltage of the battery cell CE may be lowered to the open-circuit voltage. The second stabilization period D2-2 may be a preset period, and may be set to a time period sufficient for the voltage of the battery cell CE to be lowered to the open-circuit voltage. For example, the second stabilization period D2-2 may be set to 2 hours.

In the second stabilization period D2-2, the voltage of the battery cell CE may be stabilized to be lowered to the open-circuit voltage and then further lowered by self-discharge. Within the second stabilization period D2-2, it may not be clear to distinguish between a period in which the voltage is lowered due to stabilization of the battery cell CE and a period in which the voltage is lowered due to self-discharge. Accordingly, the processor 100 may estimate the minimum voltage of the battery cell CE as the second voltage V2 within the second stabilization period D2-2. When self-discharge is in progress within the second stabilization period D2-2, the end timing of the second stabilization period D2-2 and the start timing t1 of the self-discharge period may coincide.

After the second stabilization period D2-2, the battery cell CE may be self-discharged in a discharge period D3-2.

The discharge period D3-2 may end at the timing when the vehicle resumes operation. For example, the processor 100 may determine the end of the discharge period D3-2 in response to the ignition-on (IG on) signal.

The processor 100 may determine the voltage of the battery cell CE measured at the end timing of the discharge period D3-2 as the second voltage V2. In more detail, the processor 100 may determine, as the second voltage V2, the voltage of the battery cell CE measured within a certain time from the timing at which the ignition-on signal is detected. Alternatively, the processor 100 may obtain the minimum voltage as the second voltage V2 among the voltages of the battery cell CE measured in the period before the ignition-on signal is detected.

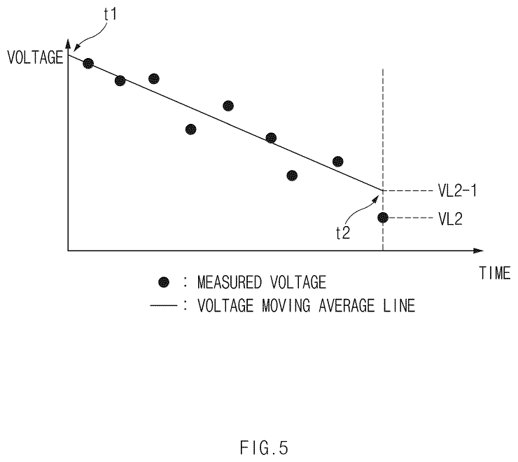

FIG. 5 is a diagram illustrating a method of obtaining an end voltage of a self-discharge period according to another embodiment. The end voltage of the self-discharge period may refer to the second voltage V2.

Referring to FIG. 5, the first timing t1 may refer to the start timing of the self-discharge period, and may be the timing at which the first voltage V1 is measured in the first stabilization period D2-1 of FIG. 3 or the second stabilization period D2-2 of FIG. 4.

The second timing t2 may refer to the end timing of the self-discharge period. When the measured voltage of the battery cell CE is “VL2” at the second timing t2, the processor 100 may determine the second voltage as “V2”. When the measured voltage is determined as the second voltage, the error of the voltage sensor 20 may be reflected.

In order to correct the error of the voltage sensor 20, the processor 100 may obtain a voltage moving average line based on the measured voltages obtained from the first timing t1 to the second timing t2.

Then, the processor 100 may obtain VL2-1 corresponding to the voltage value of the voltage moving average line at the second timing t2 as the second voltage.

The processor 100 may determine the self-discharge capacity in the self-discharge period in order to determine the self-discharge current.

The self-discharge capacity in the self-discharge period may be a deviation between the first SOC at the first timing t1 and the second SOC at the second timing t2. The processor 100 may determine the first SOC and the second SOC based on an OCV-SOC table. Following Table 1 is one example of the OCV-SOC table.

TABLE 1

| OCV (V) | SOC | BOL (SOH = 100%) | | BOL (SOH = 90%) | |
|---|---|---|---|---|---|
| 2.7 | 0% | 0 | Ah | 0 | Ah |
| 3.0 | 8% | 5.6 | Ah | 5.04 | Ah |
| 3.3 | 17% | 11.9 | Ah | 10.71 | Ah |
| 3.6 | 60% | 42 | Ah | 37.8 | Ah |
| 3.9 | 90% | 63 | Ah | 56.7 | Ah |
| 4.2 | 100% | 70 | Ah | 63 | Ah |

In Table 1, the third column represents the beginning of life (BOL) of the battery cell CE in a state where the state of health (SOH) of the battery cell CE is 100%, and the fourth column represents the BOL of the battery cell CE in a state where the SOH of the battery cell CE is 90%.

When using the OCV-SOC table of Table 1, based on the first voltage V1 being measured at the first timing t1 as 3.9V, the processor 100 may use the OCV-SOC table of Table 1 to determine the first SOC as 90%. In addition, based on the fact that the second voltage V2 at the second timing t2 is measured as 3.6V, the processor 100 may use the OCV-SOC table of Table 1 to determine the second SOC as 60%.

The processor 100 may determine the difference between the first SOC and the second SOC as self-discharge capacity. For example, when the first SOC is 90 and the second SOC is 60, the processor 100 may obtain a self-discharge capacity of 30 Ah.

The processor 100 may obtain the self-discharge current by dividing the self-discharge capacity by the self-discharge period. For example, when the self-discharge capacity is 30 Ah and the time period from the first timing t1 to the second timing t2 is 6 hours, the self-discharge current may be determined as 5 A.

According to another embodiment, the processor 100 may obtain a second self-discharge capacity by subtracting the capacity consumed by the voltage sensor 20 from the self-discharge capacity. Then, the self-discharge current may be determined by dividing the second self-discharge capacity by the self-discharge period. For example, when the self-discharge capacity is 30 Ah and the capacity consumed by the voltage sensor 20 during the self-discharge period is 12 Ah, the second self-discharge capacity may be determined as 18 Ah. In addition, when the self-discharge period is 6 hours, the self-discharge current may be determined as 3 A.

In S220, the processor 100 may determine the average voltage of the battery cell in the self-discharge period.

For example, when the first voltage V1 is 3.9 V and the second voltage V2 is 3.6 V, the average voltage of the battery cell CE may be determined as 3.75 V.

In S230, the processor 100 may determine the total self-discharge resistance of the battery cell CE based on the self-discharge current and average voltage.

The total self-discharge resistance of the battery cell CE may be obtained by dividing the self-discharge current by the average voltage.

In S240, the processor 100 may determine the short circuit resistance based on the total self-discharge resistance of the battery cell CE. In addition, when the short circuit resistance is equal to or less than a preset threshold resistance, the short circuit risk may be notified.

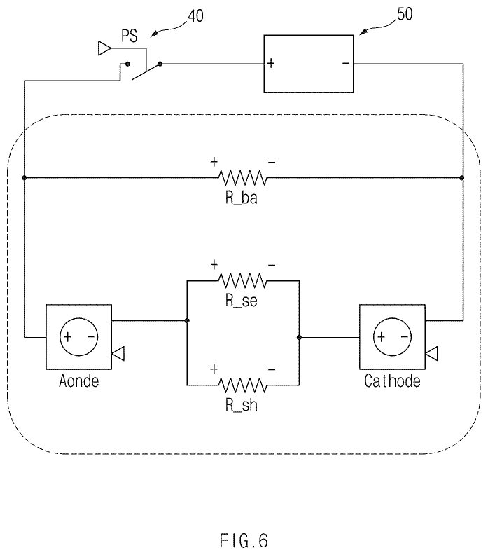

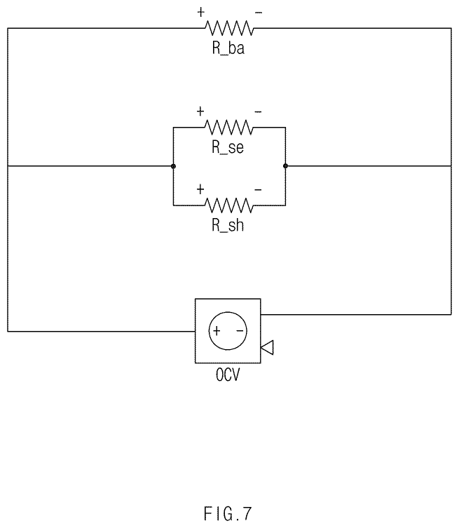

With reference to FIGS. 6 and 7, a scheme of determining the short circuit resistance based on the total self-discharge resistance of the battery cell will be described below.

FIG. 6 is a diagram illustrating modeling of a battery cell. FIG. 7 is a diagram illustrating a battery cell modeled by simplifying anode and cathode electrodes shown in FIG. 6 into OCV.

Referring to FIGS. 6 and 7, the total self-discharge resistance of the battery cell CE may include a balancing resistance R_ba, a separator resistance R_se, and a short circuit resistance R_sh.

The balancing resistance R_ba may refer to the resistance of a balancing switch. The balancing switch may be used to reduce the voltage difference between the battery cells Cell #1 to Cell #n. The battery cell CE having a higher OCV by a certain level than the battery cell CE having the lowest OCV may be discharged through the operation of the balancing switch. The balancing resistance R_ba may be determined and stored in advance.

The separator resistance R_se may refer to the resistance of a separator that separates the anode and cathode of the battery cell CE. The separator resistance R_se may be determined and stored in advance.

The short circuit resistance R_sh may refer to a resistance component generated by a short circuit phenomenon between the anode and cathode of the battery cell CE.

As shown in FIGS. 6 and 7, a total self-discharge resistance R_total of the battery cell CE may include the balancing resistance R_ba, the separator resistance R_se and the short circuit resistance R_sh. Because the balancing resistance R_ba, the separator resistance R_se, and the short circuit resistance R_sh are connected in parallel between the anode and the cathode, the total self-discharge resistance R_total of the battery cell CE is expressed as following Equation 1.

$$\frac{1}{{R}_{total}} = \frac{Self discharge current}{A v erage voltage} = \frac{1}{R\_se} + \frac{1}{R\_sh} + \frac{1}{R\_ba} \qquad Equation l$$

Equation 1 may be expressed as (1/Rₜₒₜₐₗ)−(1/R_se)−(1/R_ba)=1/R_sh. That is, the processor 100 may obtain the short circuit resistance R_sh based on the reciprocal of the balancing resistance R_ba and the reciprocal of the separator resistance R_se in the reciprocal of the total self-discharge resistance R_total.

When a short circuit does not occur, the short circuit resistance R_sh ideally approaches infinity, so the size determined from (1/Rₜₒₜₐₗ)−(1/R_se)−(1/R_sh) may be ‘0(zero)’.

In addition, as the short circuit becomes more severe, the short circuit resistance R_sh may be determined to be of a smaller size.

The processor 100 may warn of a short circuit risk when the short circuit resistance R_sh is equal to or less than a preset threshold resistance.

Equation 1 may assume that the balancing switch maintains the turn-on state. The balancing switch may maintain the turn-on state when performing a balancing function. Therefore, by reflecting the operation of the balancing switch, Equation 1 may be expressed as following Equation 2.

$$\frac{1}{{R}_{tatal}} = \frac{Self discharge current}{A v erage voltage} = \frac{1}{R\_se} + \frac{1}{R\_sh} + \frac{1}{R\_ba} * ( \frac{{t}_{balancing} * duty}{{t}_{total}} ) \qquad Equation 2$$

In Equation 2, tₜₒₜₐₗ may mean a self-discharge period, and t_{balancing} may be a period during which the balancing function is performed. Duty may mean a duty ratio corresponding to the period during which the balancing switch is turned on in the balancing period. For example, when the balancing period is 1 minute and the balancing switch maintains the turn-on state for 20 seconds, the duty may be ⅓.

The processor 100 may determine the short circuit resistance R_sh based on Equation 2 and notify the short circuit risk based on the size of the short circuit resistance R_sh.

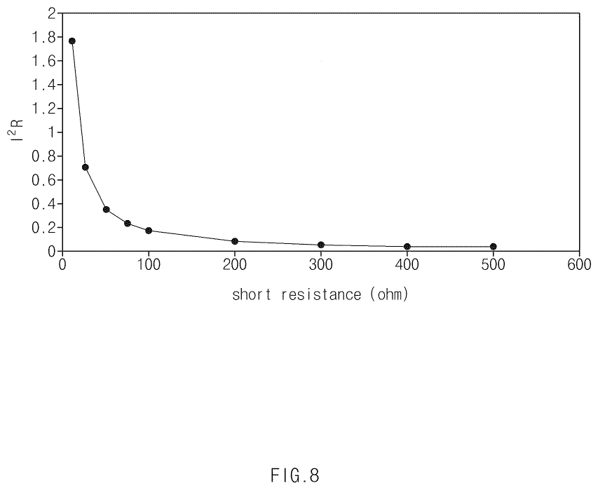

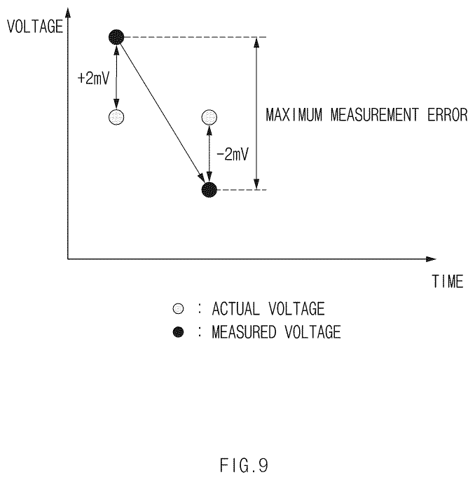

The method of setting a threshold resistance, which is a reference for determining the short circuit risk, will be described below with reference to FIGS. 8 and 9.

FIG. 8 is a diagram illustrating the tendency of heat generation due to short circuit resistance. FIG. 8 illustrates the change in heat generation factor due to short circuit resistance. The heat generation factor may be a factor that determines an amount of generated heat. In other words, the amount of heat generated by the current may be proportional to I²×R_sh×t, and I²×R_sh×t may be referred to as the heat generation factor. In the heat generation factor, I² may refer to the discharge current, R_sh may refer to the short circuit resistance, and t may refer to the time during which the current flows. As shown in FIG. 8, the heat generation factor tends to increase as the short circuit resistance (R_sh) decreases, and in particular, when the short circuit resistance (R_sh) is below a certain size, it tends to increase rapidly.

The threshold resistance may be used to determine the short circuit risk based on the amount of generated heat. In order to detect only a hard short that may cause high heat generation, the size of the threshold resistance may be set to be small. Alternatively, in order to detect a soft short that may cause relatively low heat generation, the size of the threshold resistance may be set to be large.

In addition, the threshold resistance is not fixed to a constant value, but may vary depending on the self-discharge period. The short circuit resistance may vary depending on the error of the voltage sensor. The error of the voltage sensor will be described in detail below.

FIG. 9 is a diagram illustrating the error of a voltage sensor.

Referring to FIG. 9, the voltage measured by the voltage sensor 20 may have an error with the actual voltage of the battery cell CE. When the accuracy of the voltage sensor 20 is ±2 mV, the maximum measurement error may be 4 mV. The maximum measurement error may be determined by the accuracy of the voltage sensor 20 and may not vary over time.

However, the size of the short circuit resistance may vary depending on time. In the process of determining the total self-discharge resistance R_total, the self-average current may be inversely proportional to the self-discharge period. Because the total self-discharge resistance R_total is inversely proportional to the self-average current, the total self-discharge resistance R_total may be proportional to the self-discharge period. That is, the longer the self-discharge period, the greater the total self-discharge resistance R_total may be determined, and the shorter the self-discharge period, the smaller the total self-discharge resistance R_total may be determined. Because the balancing resistance R_ba and the separator resistance R_se may be determined regardless of the self-discharge period and the error of the voltage sensor 20, the size of the total self-discharge resistance R_total may be proportional to the size of the short circuit resistance R_sh. That is, the longer the self-discharge period, the larger the short circuit resistance (R_sh) may be determined, and the shorter the self-discharge period, the smaller the short circuit resistance R_sh may be determined. Accordingly, the processor 100 may set the threshold resistance to be larger as the self-discharge period increases.

In addition, even when voltage sensor errors are the same, the shorter the self-discharge period, the larger the error in self-discharge current may be, so the reliability of the determined short circuit resistance R_sh may be lowered. Accordingly, the processor 100 may skip the procedure for determining the short circuit resistance R_sh when the self-discharge period is less than a preset threshold time.

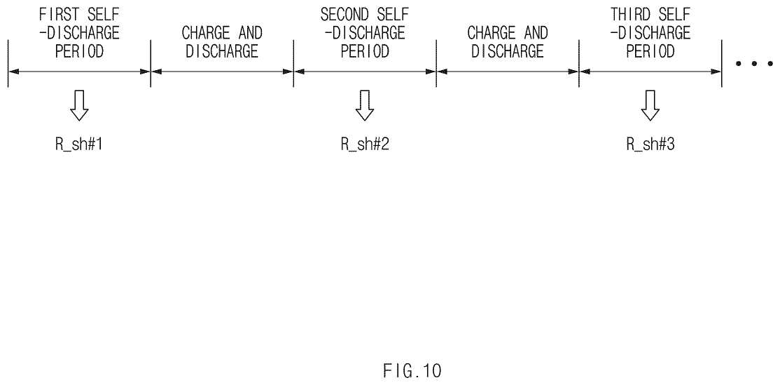

FIG. 10 is a diagram illustrating a method of determining a short circuit risk according to another embodiment of the present disclosure.

Referring to FIG. 10, the processor 100 may determine the short circuit resistance for each self-discharge period and determine the short circuit risk based on the change in the short circuit resistance.

For example, the processor 100 may obtain the first short circuit resistance R_sh in the first self-discharge period. When the first short circuit resistance R_sh is equal to or less than a preset threshold resistance, the processor 100 may notify a short circuit risk. When the first short circuit resistance R_sh exceeds the threshold resistance, the processor 100 may store the first short circuit resistance R_sh in a memory.

The processor 100 may obtain the second short circuit resistance R_sh in the second self-discharge period. When the second short circuit resistance R_sh is equal to or less than the preset threshold resistance, the processor 100 may notify a short circuit risk. When the second short circuit resistance R_sh exceeds the threshold resistance, the processor 100 may store the second short circuit resistance R_sh in a memory. In addition, the processor 100 may compare the first short circuit resistance R_sh and the second short circuit resistance R_sh. When the second short circuit resistance R_sh is smaller than the first short circuit resistance R_sh, the processor 100 may count the number of times the short circuit resistance decreases.

Likewise, the processor 100 may acquire the third short circuit resistance R_sh in the third self-discharge period. When the third short circuit resistance R_sh is equal to or less than the preset threshold resistance, the processor 100 may notify a short circuit risk, and when the third short circuit resistance R_sh exceeds the threshold resistance, the processor 100 may store the third short circuit resistance R_sh in a memory. In addition, the processor 100 may compare the second short circuit resistance R_sh and the third short circuit resistance R_sh. When the third short circuit resistance R_sh is less than the second short circuit resistance R_sh, the processor 100 may count the number of times the short circuit resistance decreases.

When the short circuit resistance exceeds the threshold resistance, the processor 100 may determine a change in the short circuit resistance, and when the number of decreases in the short circuit resistance is greater than a preset threshold value, the processor 100 may notify the short circuit risk.

As described above, when the short circuit resistance shows a tendency to decrease over a certain period of time, the processor 100 may notify a short circuit risk.

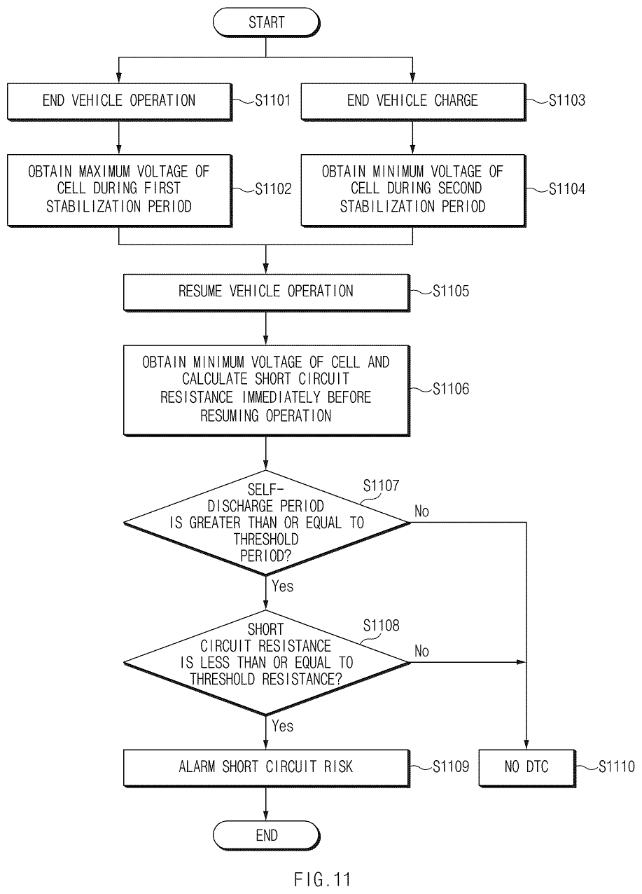

FIG. 11 is a flowchart illustrating a method of managing a battery according to another embodiment of the present disclosure. FIG. 11 illustrates procedures that may be controlled by the processor shown in FIG. 1. With reference to FIG. 11, a method of managing a battery according to another embodiment of the present disclosure may be described below.

Operations S1101, S1102, S1103, and S1104 describe procedures for obtaining the first voltage V1 at the start timing in the self-discharge period. Operations S1101 and S1102 describe a method of obtaining the first voltage V1 of the self-discharge period after vehicle operation ends. Operation S1103 and S1104 describe a method of obtaining the first voltage V1 in the self-discharge period after the charging of the battery cell CE is terminated.

In operations S1101 and S1102, the processor 100 may obtain the maximum voltage of a cell during the first stabilization period D2-1 based on the end of vehicle operation.

The processor 100 may determine that vehicle operation ends based on the detection of the ignition-off (IG-off) signal.

The processor 100 may monitor the voltage of the battery cell CE measured by the voltage sensor 20 during the first stabilization period D2-1. In addition, the processor 100 may determine the highest voltage within the first stabilization period D2-1 as the first voltage V1.

In operations S1103 and S1104, the processor 100 may obtain the minimum voltage of the cell during the second stabilization period D2-2 based on the completion of vehicle charging.

The processor 100 may monitor the voltage of the battery cell CE measured by the voltage sensor 20 during the second stabilization period D2-2. In addition, the processor 100 may determine the lowest voltage within the second stabilization period D2-2 as the first voltage V1.

In operation S1105, the processor 100 may determine whether vehicle operation begins.

The processor 100 may determine whether vehicle operation begins based on the ignition-on signal.

In operation S1106, the processor 100 may obtain the minimum voltage of the battery cell CE immediately before resuming operation. In addition, the processor 100 may determine the short circuit resistance.

The processor 100 may obtain, as the second voltage V2, the minimum voltage among the voltages of the battery cell CE before the ignition-on signal is detected.

In addition, the processor 100 may determine the self-discharge capacity based on the first voltage V1 and the second voltage V2. The processor 100 may determine the self-discharge capacity based on Table 1 described above.

In addition, the processor 100 may obtain the self-discharge current obtained by dividing the self-discharge capacity by the self-discharge period. The self-discharge period may be a period from the timing at which the first voltage V1 is obtained to the timing at which the second voltage V2 is obtained.

In addition, the processor 100 may determine the total self-discharge resistance R_total by dividing the self-discharge current by the average voltage. The average voltage may be the average of the first voltage V1 and the second voltage V2.

In addition, the processor 100 may determine the short circuit resistance based on the total self-discharge resistance R_total, the balancing resistance R_ba and the separator resistance R_se. The short circuit resistance may refer to the resistance in the short area when a short circuit occurs in a battery cell CE. The processor 100 may determine the short circuit resistance based on Equation 1 or Equation 2 described above.

In operation S1107, the processor 100 may determine whether the self-discharge period is greater than or equal to the threshold period. The threshold period may be a reference for determining whether the reliability of the determined short circuit resistance R_sh is admittible.

In operation S1108, based on the fact that the self-discharge period is greater than or equal to the threshold period, the processor 100 may determine whether the short circuit resistance R_sh is less than or equal to the threshold resistance.

In operation S1109, based on the fact that the short circuit resistance R_sh is less than or equal to the threshold resistance, the processor 100 may notify the short circuit risk through the alarm device 60. For example, the processor 100 may generate a diagnostic trouble code (DTC) and proceed with a procedure corresponding to the DTC. The processor 100 may inform vehicle occupants of the short circuit risk of the battery cell CE through the alarm device 60 according to the DTC. In addition, the processor 100 may notify an external server of the short circuit risk of the battery cell CE through a communication device.

In operation S1110, the processor 100 may not generate a DTC based on the fact that the self-discharge period is less than the threshold period or the short circuit resistance exceeds the threshold resistance.

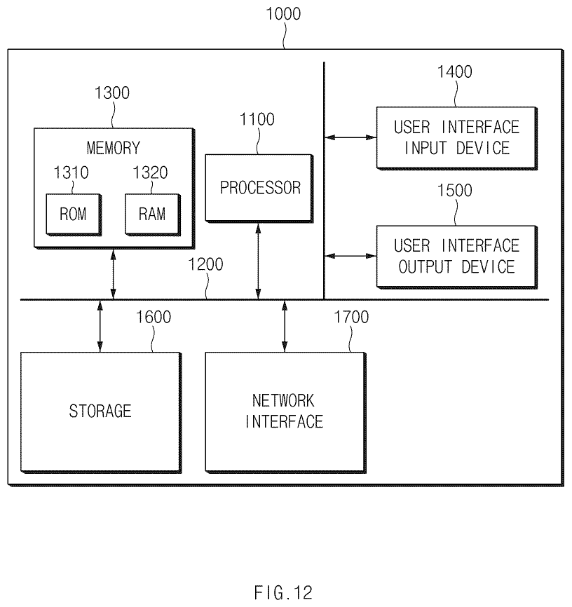

FIG. 12 is a block diagram illustrating a computing system according to an embodiment of the present disclosure.

Referring to FIG. 12, a computing system 1000 may include at least one processor 1100, a memory 1300, a user interface input device 1400, a user interface output device 1500, storage 1600, and a network interface 1700 connected through a bus 1200.

The processor 1100 may be a central processing device (CPU) or a semiconductor device that processes instructions stored in the memory 1300 and/or the storage 1600. The memory 1300 and the storage 1600 may include various types of volatile or non-volatile storage media. For example, the memory 1300 may include a ROM (Read Only Memory) and a RAM (Random Access Memory).

Accordingly, the processes of the method or algorithm described in relation to the embodiments of the present disclosure may be implemented directly by hardware executed by the processor 1100, a software module, or a combination thereof. The software module may reside in a storage medium (that is, the memory 1300 and/or the storage 1600), such as a RAM, a flash memory, a ROM, an EPROM, an EEPROM, a register, a hard disk, solid state drive (SSD), a detachable disk, or a CD-ROM.

The exemplary storage medium is coupled to the processor 1100, and the processor 1100 may read information from the storage medium and may write information in the storage medium. In another method, the storage medium may be integrated with the processor 1100. The processor and the storage medium may reside in an application specific integrated circuit (ASIC). The ASIC may reside in a user terminal. In another method, the processor and the storage medium may reside in the user terminal as an individual component.

According to the embodiments of the present disclosure, it is possible to determine a short circuit risk based on the self-discharge of a battery cell.

In addition, according to the embodiments of the present disclosure, because the short circuit risk of a battery cell is determined based on the self-discharge capacity in the process of using the battery cell, it is possible to detect an occurrence of a short circuit inside the battery cell due to deterioration and impact after manufacturing the battery cell.

In addition, according to the embodiments of the present disclosure, it is possible to detect the short circuit risk differently by adjusting the size of the threshold resistance, which is a reference for determining the short circuit risk.

In addition, various effects that are directly or indirectly understood through the present disclosure may be provided.

Although exemplary embodiments of the present disclosure have been described for illustrative purposes, those skilled in the art will appreciate that various modifications, additions and substitutions are possible, without departing from the scope and spirit of the disclosure.

Therefore, the exemplary embodiments disclosed in the present disclosure are provided for the sake of descriptions, not limiting the technical concepts of the present disclosure, and it should be understood that such exemplary embodiments are not intended to limit the scope of the technical concepts of the present disclosure. The protection scope of the present disclosure should be understood by the claims below, and all the technical concepts within the equivalent scopes should be interpreted to be within the scope of the right of the present disclosure.

1. An apparatus for managing a battery, the apparatus comprising:
a voltage sensor configured to measure a voltage of a battery cell mounted on a vehicle; and
a processor configured to determine a short circuit risk of the battery cell;
wherein the processor is configured to:
determine a self-discharge current of the battery cell during a self-discharge period in which a voltage drop of the battery cell occurs;
determine an average voltage of the battery cell during the self-discharge period;
determine a total self-discharge resistance of the battery cell based on the self-discharge current and the average voltage;
determine a short circuit resistance of the battery cell based on the total self-discharge resistance; and
notify a short circuit risk based on a fact that the short circuit resistance is less than a threshold resistance.

2. The apparatus of claim 1, wherein the processor is further configured to:
determine a self-discharge capacity proportional to the voltage drop; and
determine the self-discharge current by dividing the self-discharge capacity by the self-discharge period.

3. The apparatus of claim 2, wherein the processor is further configured to:
obtain a first SOC corresponding to a first voltage of the battery cell measured at a start time of the self-discharge period;
obtain a second SOC corresponding to a second voltage of the battery cell measured at an end time of the self-discharge period; and
obtain a difference between the first SOC and the second SOC as the self-discharge capacity.

4. The apparatus of claim 3, wherein the processor is further configured to determine a maximum voltage of the battery cell as the first voltage within a first preset stabilization period after operation of the vehicle is terminated.

5. The apparatus of claim 3, wherein the processor is further configured to determine a minimum voltage of the battery cell as the first voltage within a second preset stabilization period after charging of the battery cell is terminated.

6. The apparatus of claim 3, wherein the processor is further configured to determine, as the second voltage, a minimum voltage among voltages of the battery cell measured before an ignition-on signal of the vehicle is detected.

7. The apparatus of claim 3, wherein the processor is further configured to determine the average voltage by averaging the first voltage and the second voltage.

8. The apparatus of claim 1, wherein the processor is further configured to skip a procedure of determining the short circuit resistance based on a determination that the self-discharge period is less than a preset threshold period.

9. The apparatus of claim 1, wherein the processor is further configured to determine the short circuit resistance based on the total self-discharge resistance, a separator resistance of the battery cell, and a resistance of a balancing switch for balancing the battery cell.

10. The apparatus of claim 1, wherein the processor is further configured to set a size of the threshold resistance to be larger as the self-discharge period is longer.

11. The apparatus of claim 1, wherein the processor is further configured to:
determine a change in the short circuit resistance based on a determination that the short circuit resistance is less than the threshold resistance; and
notify the short circuit risk based on a determination that the short circuit resistance gradually decreases.

12. A method of managing a battery, the method comprising:
determining, by a processor, a self-discharge current of a battery cell during a self-discharge period in which a voltage drop of the battery cell occurs;
determining, by the processor, an average voltage of the battery cell during the self-discharge period;
determining, by the processor, a total self-discharge resistance of the battery cell based on the self-discharge current and the average voltage; and
determining, by the processor, a short circuit resistance of the battery cell based on the total self-discharge resistance; and
notifying, by the processor, a short circuit risk based on a fact that the short circuit resistance is less than a threshold resistance.

13. The method of claim 12, wherein determining the self-discharge current includes:
determining a self-discharge capacity proportional to the voltage drop; and
determining the self-discharge current by dividing the self-discharge capacity by the self-discharge period.

14. The method of claim 13, wherein determining the self-discharge current includes:
obtaining a first SOC corresponding to a first voltage of the battery cell measured at a start time of the self-discharge period;
obtaining a second SOC corresponding to a second voltage of the battery cell measured at an end time of the self-discharge period; and
obtaining a difference between the first SOC and the second SOC as the self-discharge capacity.

15. The method of claim 14, wherein obtaining the first SOC includes:
determining a maximum voltage of the battery cell as the first voltage within a first preset stabilization period after operation of the vehicle is terminated.

16. The method of claim 14, wherein obtaining the first SOC includes:
determining a minimum voltage of the battery cell as the first voltage within a second preset stabilization period after charging of the battery cell is terminated.

17. The method of claim 14, wherein obtaining the second SOC includes:
detecting an ignition-on signal of the vehicle; and
determining, as the second voltage, a minimum voltage among voltages of the battery cell measured before the ignition-on signal of the vehicle is detected.

18. The method of claim 14, wherein determining the average voltage includes:
obtaining the average voltage by averaging the first voltage and the second voltage.

19. The method of claim 12, further comprising:
comparing the self-discharge period with a preset threshold period; and
skipping a procedure of determining the short circuit resistance based on a determination that the self-discharge period is less than a preset threshold period.

20. The method of claim 12, wherein notifying the short circuit risk further includes:
setting a size of the threshold resistance to be larger as the self-discharge period is longer.
